(19) United States
(12) Patent Application Publication
(10) Pub. No.: US 2025/0087528 A1
(43) Pub. Date: Mar. 13, 2025

(54) FORMING ISOLATION REGIONS WITH LOW PARASITIC CAPACITANCE

(71) Applicant: Taiwan Semiconductor Manufacturing Co., Ltd., Hsinchu (TW)

(72) Inventors: Yunn-Shiuan Liu, Taipei City (TW); Li-Fong Lin, Hsinchu (TW); Chia-Hui Lin, Dajia Township (TW); Tze-Liang Lee, Hsinchu (TW)

(21) Appl. No.: 18/402,187

(22) Filed: Jan. 2, 2024

Related U.S. Application Data
(60) Provisional application No. 63/582,356, filed on Sep. 13, 2023.

(51) Int. Cl. H01L 21/762; H01L 27/088; H01L 29/06; H01L 29/40; H01L 29/423; H01L 29/66; H01L 29/775; H01L 29/786

(52) U.S. Cl. CPC H01L 21/76224; H10D 30/43; H10D 30/6735; H10D 30/6757; H10D 62/121; H10D 64/01; H10D 64/017; H10D 84/83

(57) ABSTRACT

A method includes forming a gate stack, and etching the gate stack to form a trench penetrating through the gate stack. A dielectric isolation region underlying the gate stack is exposed to the trench, and a first portion and a second portion of the gate stack are separated by the trench. The method includes performing a first deposition process to form a first dielectric layer extending into the trench and lining sidewalls of the first portion and the second portion of the gate stack, and performing a second deposition process to form a second dielectric layer on the first dielectric layer. The second dielectric layer fills the trench. The first dielectric layer has a first dielectric constant, and the second dielectric layer has a second dielectric constant greater than the first dielectric constant.

### PRIORITY CLAIM AND CROSS-REFERENCE

This application claims the benefit of the following provisionally filed U.S. patent application: Application No. 63/582,356, filed on Sep. 13, 2023, and entitled “Method of Forming Cut Metal Gate Liner by Using Low Dielectric Constant Material for Ceff Reduction;” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

The formation of the GAA transistors typically includes forming long strips (including alternating semiconductor materials) and long gate stacks, and then forming isolation regions to cut the long strips and long gate stacks into shorter portions. The shorter portions may be used to form the channel layers and the gate stacks of the GAA transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-20 illustrate the views of intermediate stages in the formation of Gate-All-Around (GAA) transistors in accordance with some embodiments.

FIG. 21 schematically illustrates a distribution profile of carbon (and/or nitrogen) in accordance with some embodiments.

FIG. 22 illustrates a process flow for forming GAA transistors in accordance with some embodiments.

FIG. 23 illustrates a process flow for forming a gate isolation region in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors, Cut-Metal-Gate (CMG) isolation regions, and the method of forming the same are provided. In accordance with some embodiments of the present disclosure, a CMG isolation region includes a first layer formed of a lower-k dielectric layer, and a higher-k dielectric layer on the lower-k dielectric layer. The lower-k dielectric layer may be formed of a low-k dielectric material (with a dielectric constant (k value) lower that of silicon oxide). The formation of the CMG isolation may be performed by selecting proper precursors and adjusting RF parameters.

In the illustrated embodiments, the formation of GAA Transistors is used as an example to explain the concept of the present disclosure. Other types of transistors such as Fin Field-Effect Transistors (FinFETs), forksheet transistors, Complementary Field-Effect Transistors (CFETs), or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

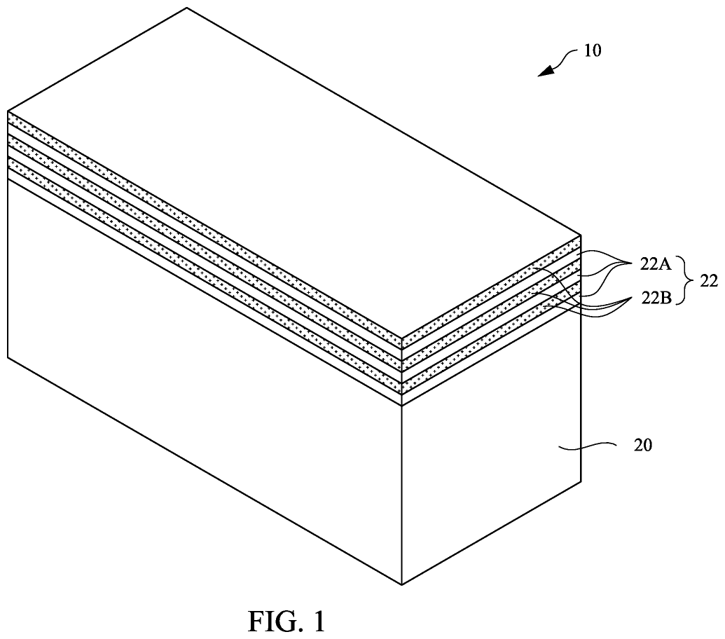

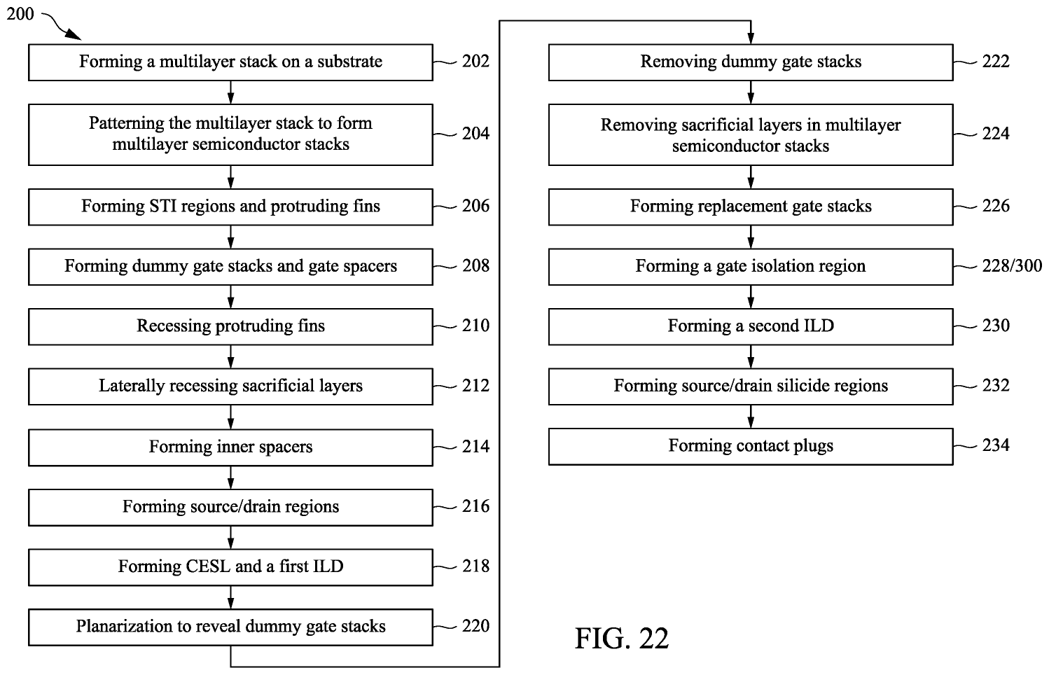

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-20 illustrate the views of intermediate stages in the formation of GAA transistors in accordance with some embodiments of the present disclosure. The corresponding processes are also reflected schematically in the process flow shown in FIG. 22.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown as in FIG. 22. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

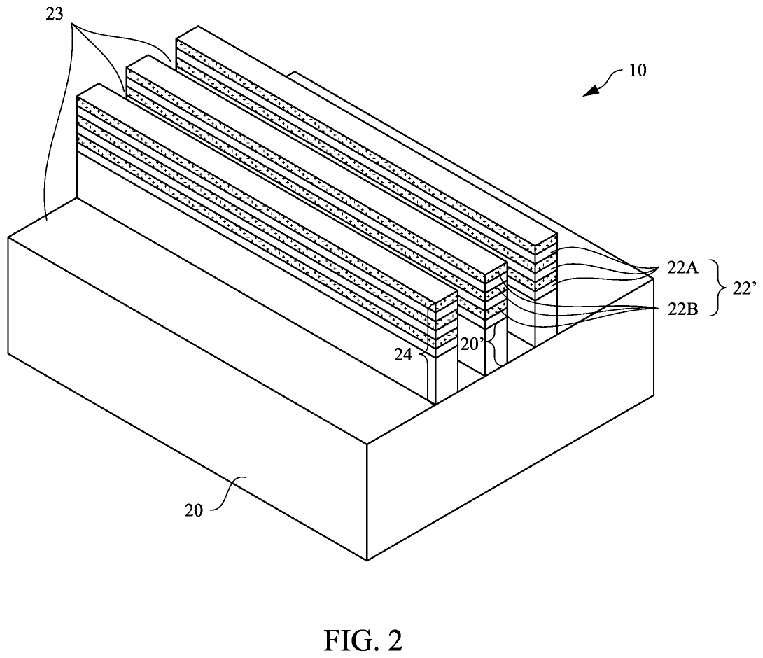

Referring to FIG. 2, multilayer stack 22 and a portion of the underlying substrate 20 are patterned in an etching process(es), so that trenches 23 are formed. The respective process is illustrated as process 204 in the process flow 200 shown as in FIG. 22. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

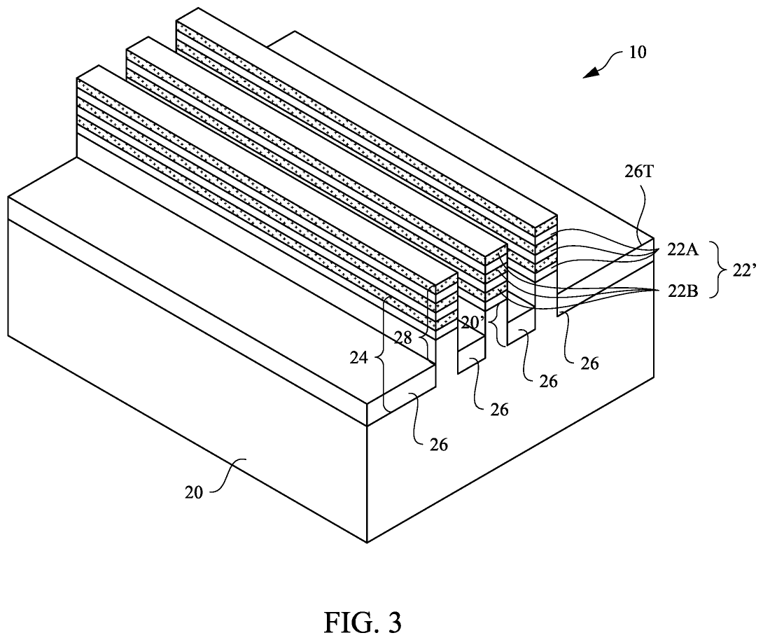

FIG. 3 illustrates the formation of isolation regions 26, which are also referred to as Shallow Trench Isolation (STI) regions throughout the description. The respective process is illustrated as process 206 in the process flow 200 shown as in FIG. 22. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

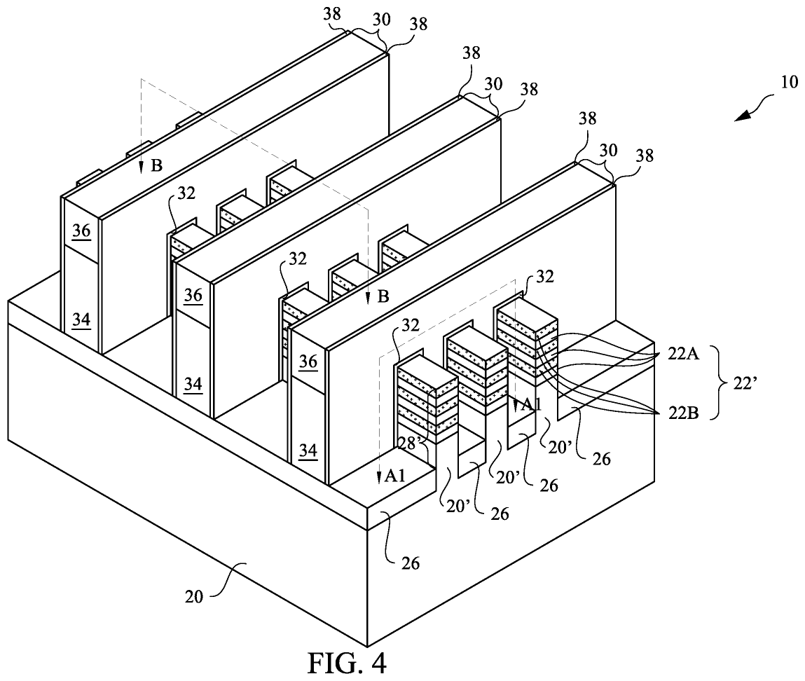

Referring to FIG. 4, dummy gate stacks 30 and gate spacers 38 are formed on the top surfaces and the sidewalls of (protruding) fins 28. The respective process is illustrated as process 208 in the process flow 200 shown as in FIG. 22. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

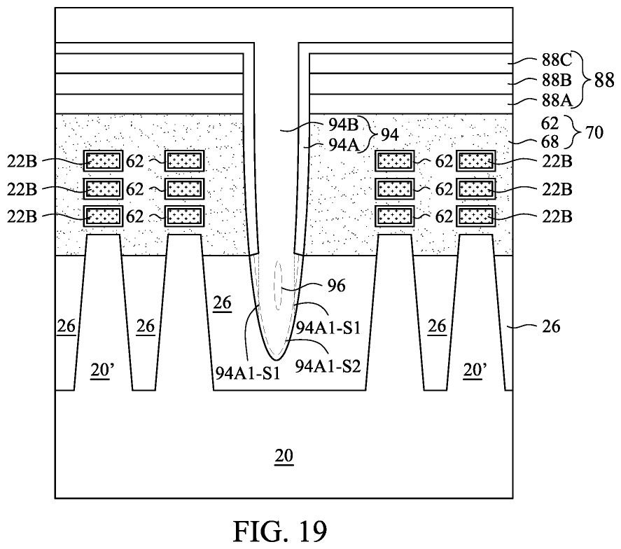

In accordance with alternative embodiments, one or more layers of gate spacers 38 may be formed using the processes as illustrated in FIG. 19, and the resulting layer of gate spacers 38 comprises the material as discussed referring to FIGS. 19 through 21. For example, gate spacers 38 may be formed of or include SiOCNH therein. The details of the formation processes are discussed in subsequent paragraphs.

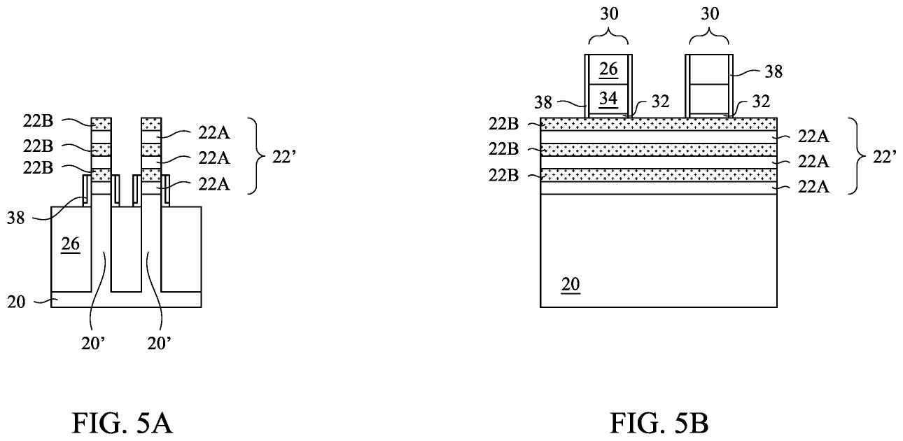

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

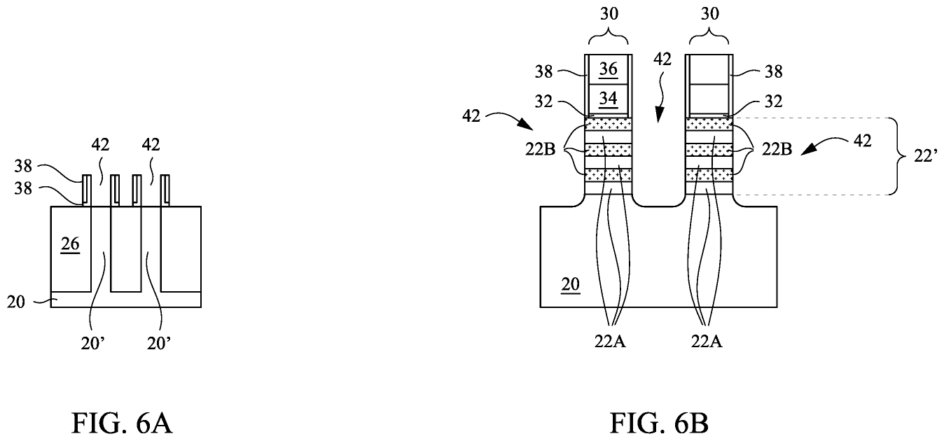

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown as in FIG. 22. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

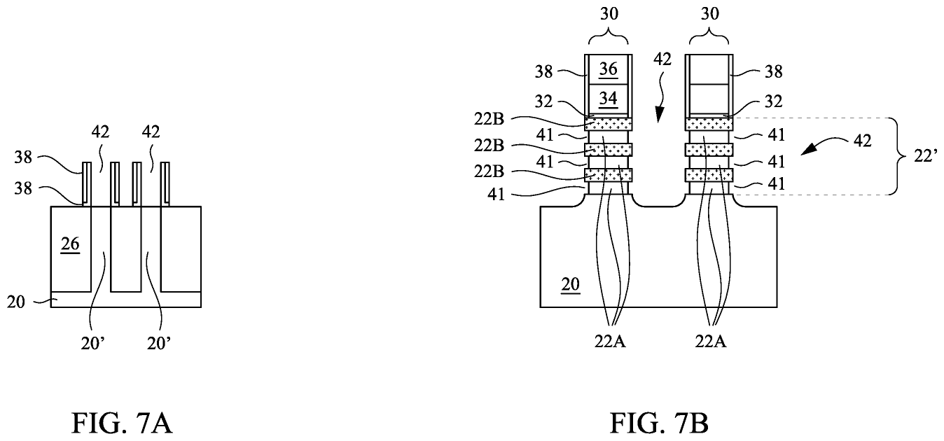

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown as in FIG. 22. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

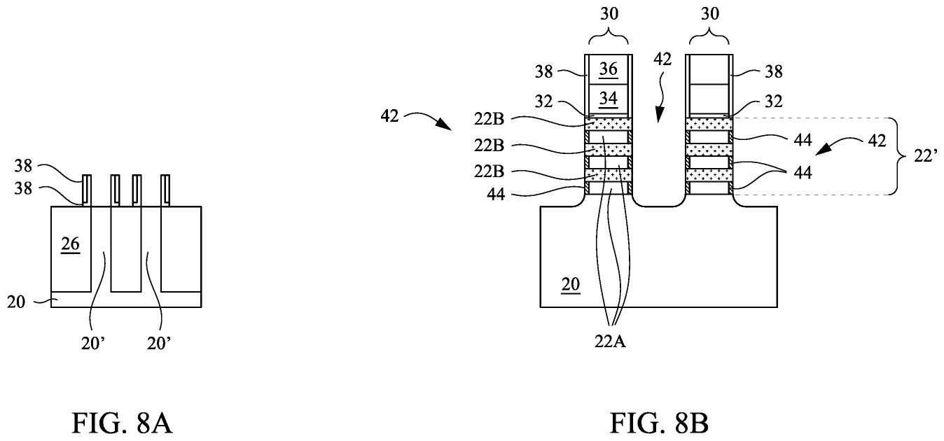

Referring to FIGS. 8A and 8B, inner spacers 44 are formed. The respective process is illustrated as process 214 in the process flow 200 shown as in FIG. 22. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

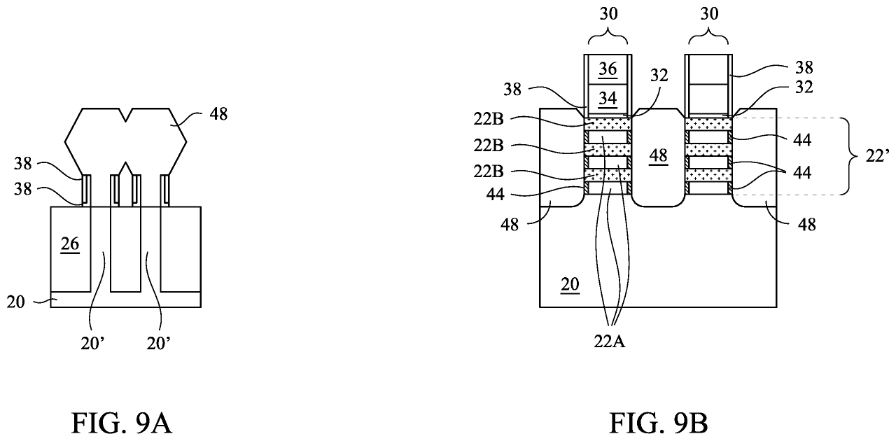

FIGS. 9A and 9B illustrate the cross-sectional views and a perspective view in the formation source/drain regions 48 in recesses 42 through epitaxy. The respective process is illustrated as process 216 in the process flow 200 shown as in FIG. 22. Source/drain region(s) may refer to a source or a drain, individually or collectively dependent upon the context. In accordance with some embodiments, the source/drain regions 48 may exert stress on the nanostructures 22B, which are used as the channels of the corresponding GAA transistors, thereby improving performance.

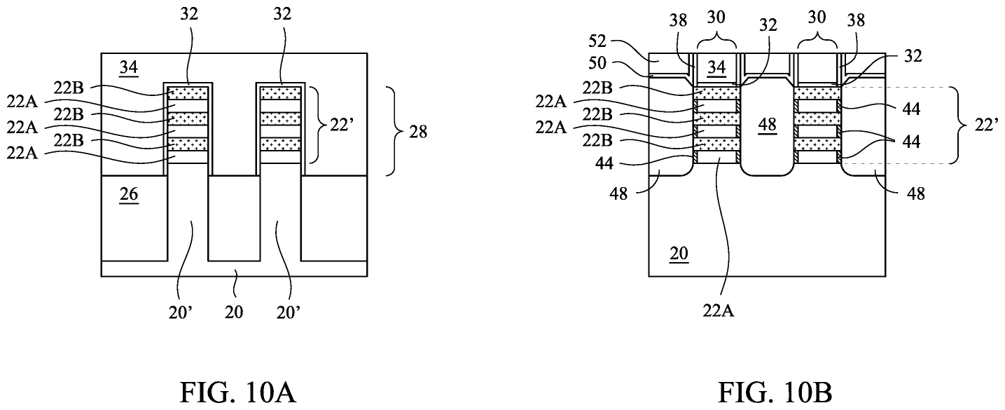

In accordance with some embodiments, the corresponding transistor is n-type, and epitaxial source/drain regions 48 are accordingly formed as n-type by doping an n-type dopant. For example, silicon phosphorous (SiP), silicon carbon phosphorous (SiCP), or the like may be grown to form epitaxial source/drain regions 48. In accordance with alternative embodiments, the corresponding transistor is p-type, and epitaxial source/drain regions 48 are accordingly formed as p-type by doping a p-type dopant. For example, silicon boron (SiB), silicon germanium boron (SiGeB), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other, with voids 49 (FIG. 10C) being formed.

After the epitaxy process, epitaxy regions 48 may be further implanted with an n-type impurity or a p-type impurity to form source and drain regions, which are also denoted using reference numeral 48. In accordance with alternative embodiments of the present disclosure, the implantation process is skipped when epitaxy regions 48 are in-situ doped with the n-type impurity or p-type impurity during the epitaxy, and the epitaxy regions 48 are also source/drain regions.

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown as in FIG. 22. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 220 in the process flow 200 shown as in FIG. 22. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

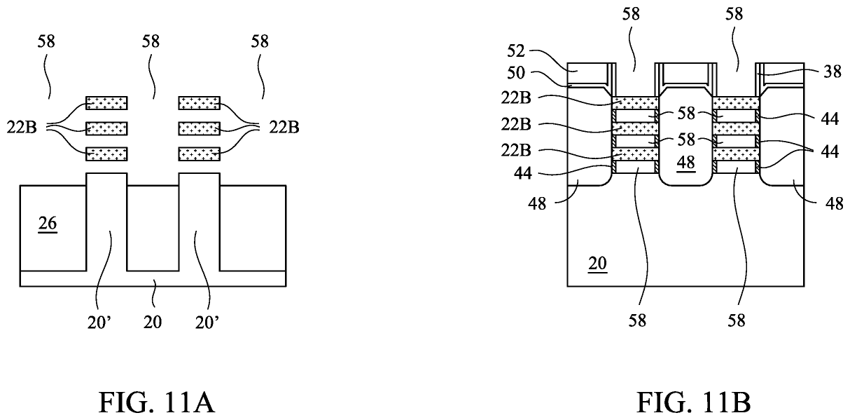

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 222 in the process flow 200 shown as in FIG. 22. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown as in FIG. 22. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH₄OH), or the like may be used to remove sacrificial layers 22A.

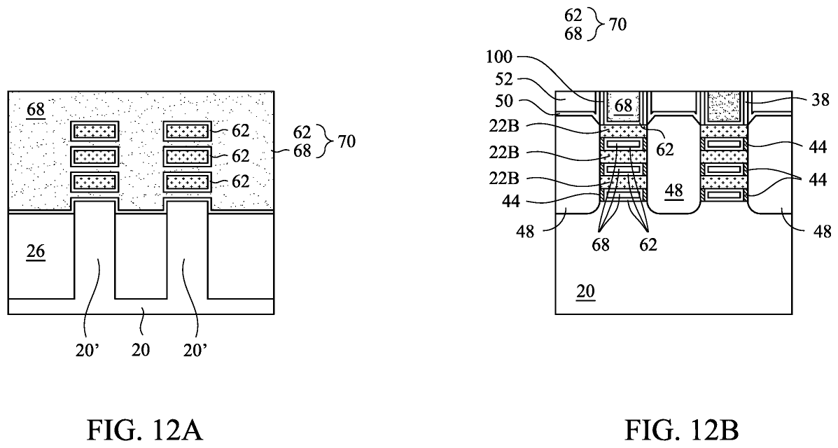

Referring to FIGS. 12A and 12B, gate dielectrics 62 and gate electrodes 68 are formed, hence forming replacement gate stacks 70. The respective process is illustrated as process 226 in the process flow 200 shown as in FIG. 22. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TIN, TaN, TiAl, TiAIC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

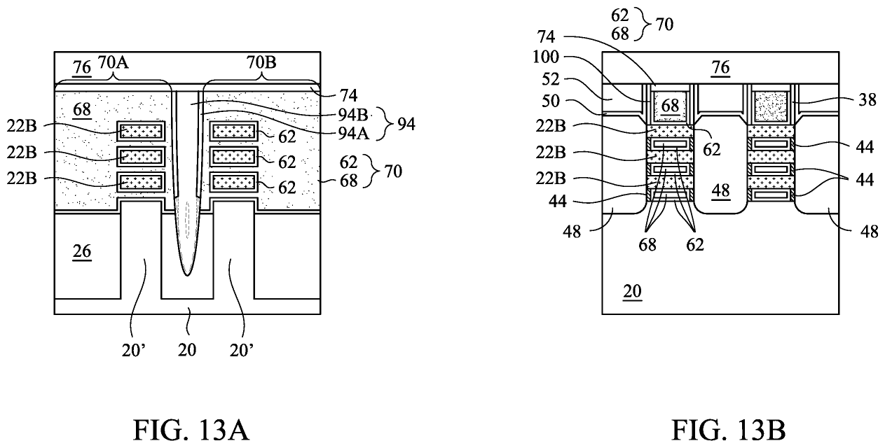

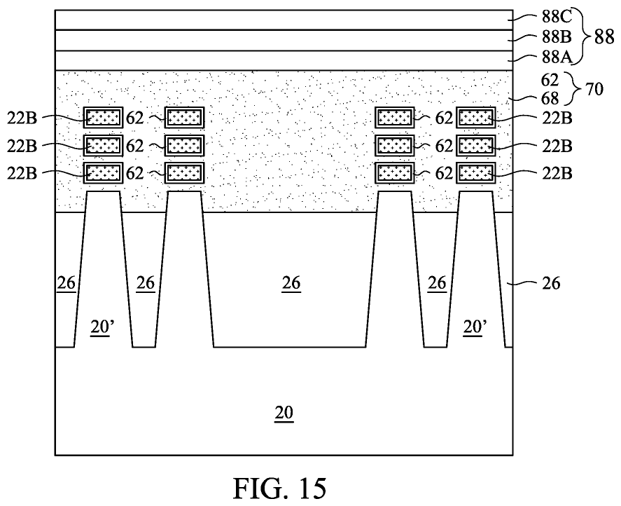

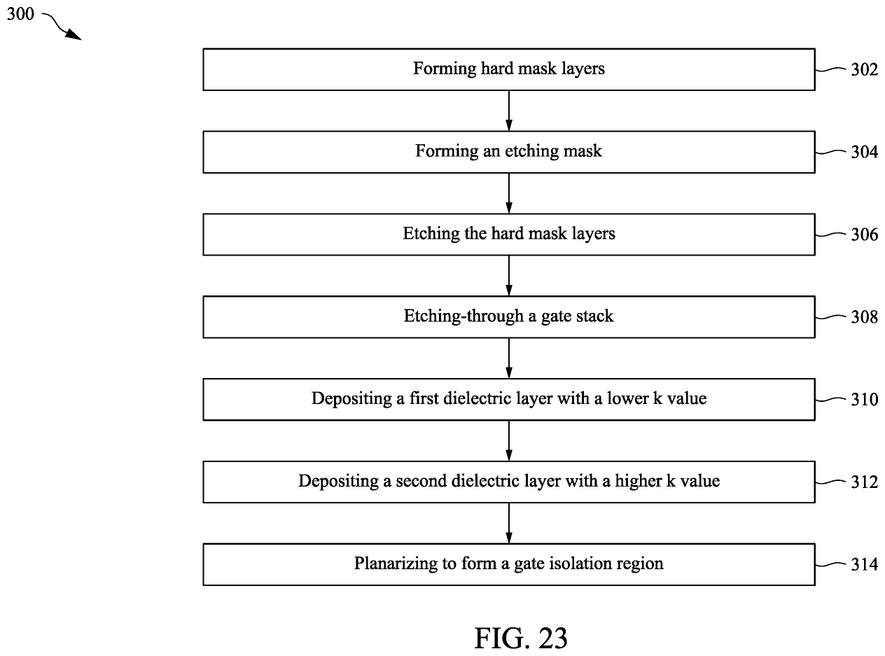

In the processes shown in FIGS. 13A and 13B, gate isolation region 94, which is also referred to as a Cut-Metal-Gate (CMG) region, is formed to separate (cut) gate stack 70. Gate stack 70 is thus separated into two portions 70A and 70B, which are electrically isolated from each other, and are collectively referred to as gate stacks 70. The details for forming gate isolation region 94 are discussed in detail referring to FIGS. 15-20. The respective process is illustrated as process 228 in the process flow 200 shown as in FIG. 22. The respective process is also illustrated in detail as process flow 300 shown in FIG. 23.

Further referring to FIGS. 13A and 13B, gate stacks 70 are recessed, so that recess (occupied by gate isolation region 94) is formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 13A and 13B, ILD 76 is deposited over ILD 52 and over gate masks 74. The respective process is illustrated as process 230 in the process flow 200 shown as in FIG. 22. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

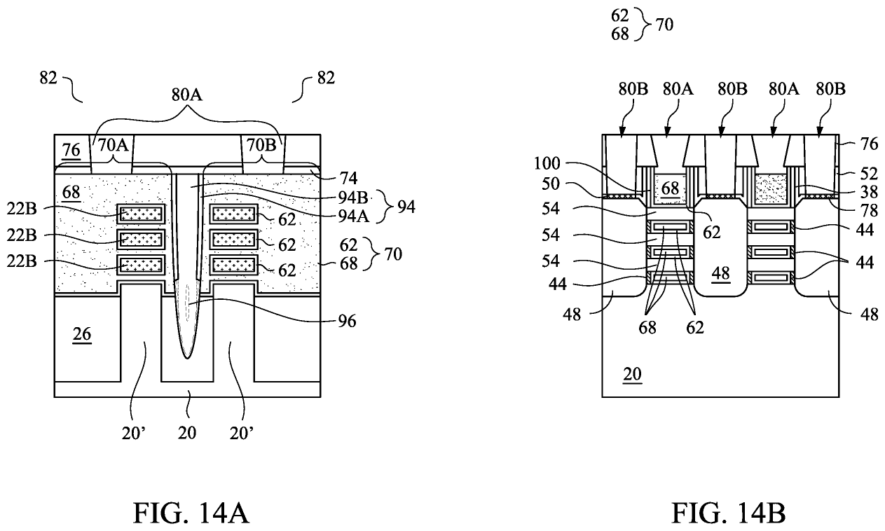

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process(es), such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 232 in the process flow 200 shown as in FIG. 22. Contact plugs 80B are then formed over silicide regions 78. Also, contacts 80A (may also be referred to as gate contact plugs) are formed in the recesses, and are over and contacting gate electrodes 68. The respective process is illustrated as process 234 in the process flow 200 shown as in FIG. 22. Transistor 82 is thus formed.

FIGS. 15 through 20 illustrate the formation of gate isolation region 94 in accordance with some embodiments. The corresponding processes are shown in the process flow 300 as in FIG. 23. FIG. 15 illustrates a cross-sectional view of an intermediate structure, which is also shown in FIG. 12A, in which gate stack 70 has been formed, and includes gate dielectrics 62 and gate electrode 68.

In accordance with some embodiments, hard mask layer 88 is deposited, and may include a multi-layer structure including a plurality of layers. The respective process is illustrated as process 302 in the process flow 300 as shown in FIG. 23. In accordance with some embodiments, hard mask layers 88 include silicon nitride layer 88A, silicon layer 88B, and silicon nitride layer 88C. In accordance with alternative embodiments, a single-layer hard mask 88 is used, which may be formed of or comprise silicon nitride.

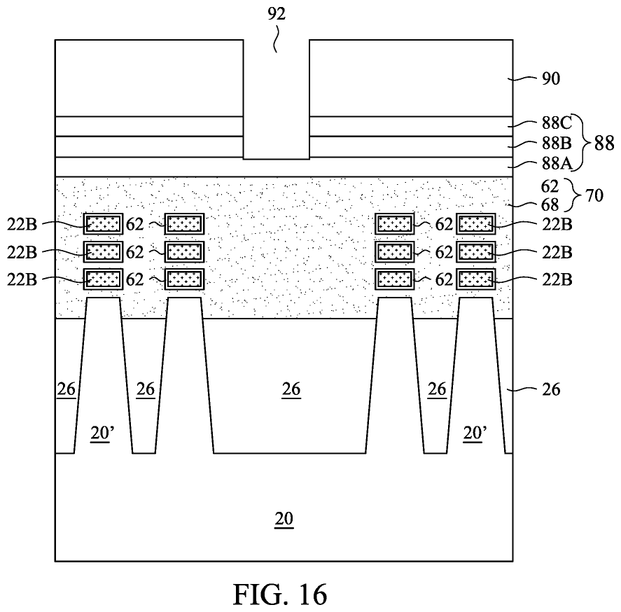

Etching mask 90 is then formed, as shown in FIG. 16. The respective process is illustrated as process 304 in the process flow 300 as shown in FIG. 23. Etching mask 90 may also have a single-layer structure (which may include a photoresist) or a dual-layer structure including a Bottom Anti-reflective Coating (BARC) and a photoresist. Alternatively, etching mask 90 may have a tri-layer, which may include a bottom layer, a middle layer over the bottom layer, and a top layer, which may be a patterned photoresist. Trench 92 is formed in etching mask 90.

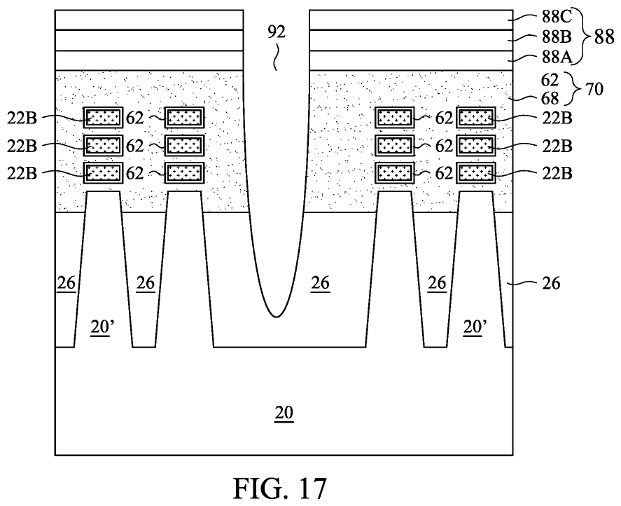

Next, etching mask 90 is used to etch mask layers 88, so that trench 92 extends into hard mask layers 88. The respective process is illustrated as process 306 in the process flow 300 as shown in FIG. 23. The resulting structure is shown in FIG. 17. In accordance with some embodiments, the etching process includes a main etching process followed by an over-etching process. Depending on the materials of mask layers 88, the main etching process may be performed using process gases selected from CH₂F₂, CF₄, O₂, Ar, and combinations thereof. The over-etching process may be performed using process gases selected from CH₃F, O₂, Ar, and combinations thereof. The etching may be anisotropic. In accordance with some embodiments, trench 92 extends to the top surface of hard mask 88A. Etching mask 90 may be removed after trench 92 is formed in hard mask layers 88.

Next, as shown in FIG. 17, replacement gate stack 70 is etched. The respective process is illustrated as process 308 in the process flow 300 as shown in FIG. 23. The etching of replacement gate stack 70 is anisotropic. In accordance with some embodiments, the etching is performed until STI region 26 is exposed. Trench 92 may extend into STI region 26. After the etching process, hard mask layers 88 may (or may not) be removed. Trench 92 may have a width in the range between about 10 nm and about 30 nm, and a depth in the range between about 120 nm and about 200 nm. Gate stack 70 is thus separated into gate stacks 70A and 70B.

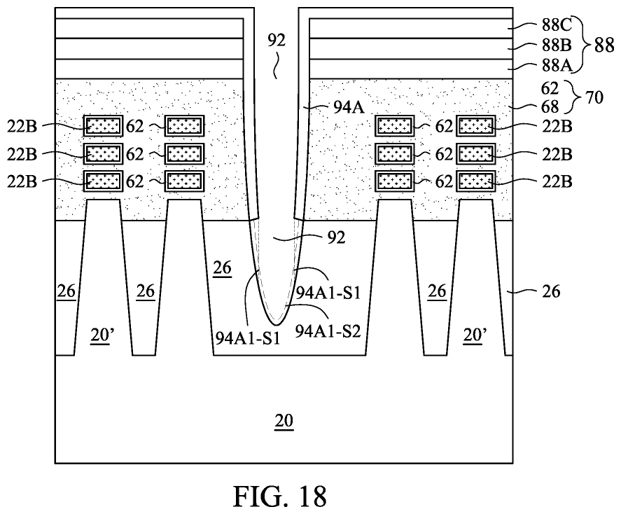

In a subsequent process, dielectric layers 94 (including dielectric layer 94A and dielectric layer 94B) are deposited, as shown in FIGS. 18 and 19. Dielectric layers 94 include some portions extending into trenches 92 to form isolation regions, and some horizontal portions over gate stack 70.

Referring to FIG. 18, dielectric layer 94A is deposited. The respective process is illustrated as process 310 in the process flow 300 as shown in FIG. 23. In accordance with some embodiments, dielectric layer 94A comprises a silicon-containing dielectric material, which may be expressed as SiCₓO_{y}N_{z}. Value x may be smaller than about 1, value y may be smaller than about 2, and value z may be smaller than 3, while these values may be outside of the above-mentioned ranges. In accordance with some embodiments, dielectric layer 94A comprises SiCON, SiCN, SION, SiCO, or the like.

Dielectric layer 94A may have a first dielectric constant (k value), which is relatively low compared to that of the subsequently deposited dielectric layer 94B. In accordance with some embodiments, dielectric layer 94A has a k value lower than about 4.0, and may be in the range between about 3.0 and about 4.0. Dielectric layer 94A thus may be a low-k dielectric layer in accordance with some embodiments, with the respective k value lower than 3.8 (the k value of silicon oxide). Dielectric layer 94A may be porous so that its k value is low.

In accordance with some embodiments, the precursors for forming dielectric layer 94A may include aminosilane or the like. The deposition method may include ALD, Plasma enhanced ALD (PEALD), CVD, Plasma enhanced CVD (PECVD), or the like. The aminosilane may have the chemical formula of C₉H₂₃NO₃Si. The aminosilane, different from the otherwise used precursors such as silane, disilane, DiChloroSilane (DCS, SiH₂Cl₂), or the like, include carbon (and nitrogen), which may contribute to the reduction of the resulting dielectric layer 94A.

Using aminosilane as the precursor may advantageously reduce the k value of the resulting dielectric layer 94A. The aminosilane, however, may adversely result in dielectric layer 94A to extend shallow in trench 92, and not able to cover the sidewalls of gate stack 70. In accordance with some embodiments, the deposition of dielectric layer 94A may be performed with plasma being generated. Experiment results have revealed that when plasma is generated using N₂, NH₃, and Ar as in the embodiments of the present disclosure, the resulting dielectric layer 94A may extend deeper into trench 92.

In accordance with some embodiments, the reduction of the dielectric layer 94A may also be achieved by adjusting the process conditions. For example, the RF power for generating the plasma may be performed with on-off cycles, which may have on-time durations in the range between about 0.1 seconds and about 15 seconds. The flow rate of N₂ may be smaller than about 6 slm. The flow rate of NH₃ may be smaller than about 6 slm. The flow rate of Ar may be smaller than about 1.5 slm. The wafer temperature may be in the range between about 200° C. and about 400° C.

By adopting aminosilane, N₂, NH₃, and Ar as precursors and adjusting process conditions, the resulting dielectric layer 94A may have a silicon atomic percentage in the range between about 20 percent and about 50 percent, an oxygen percentage in the range between about 5 percent and about 35 percent, a carbon percentage lower than about 25 percent, and a nitrogen atomic percentage lower than about 50 percent. The porosity of dielectric layer 94A may be greater than about 15 percent, and may be in the range between about 15 percent and about 45 percent. The k value of dielectric layer 94A is thus reduced.

In accordance with some embodiments, by adjusting process conditions, dielectric layer 94A has a bottommost end higher than the bottom end of trench 92. Accordingly, the upper part of trench 92 has dielectric layer 94A lining the sidewalls of gate stack 70 (and possibly STI region 26), while the bottom part of trench 92 does not have dielectric layer 94A lining thereon. Accordingly, some surfaces of the STI region 26 facing trench 26 may be exposed.

When dielectric layer 94A extends partially into trench 92, the dielectric layer 94A fully covers all exposed sidewalls of gate stacks 70A and 70B, so that the dielectric layer 94A, which has a low k value, may function to reduce the parasitic capacitance in the resulting structure such as the parasitic capacitance between neighboring gate stacks 70A and 70B. In accordance with some embodiments, the bottom ends of dielectric layer 94A are substantially level with, or slightly lower than, the interfaces between STI region 26 and the overlying gate stack 70, and hence some parts of sidewalls of STI region 26 are exposed to trench 92. By adjusting process conditions, the dielectric layer 94A are deposited better on gate stacks 70A and 70B than on SIT region 26, and hence the bottom ends of dielectric layer 94A may be abrupt, as illustrated in FIGS. 18 and 19.

In accordance with alternative embodiments, dielectric layer 94A, due to the lower ability of extending deep into trench 92, may have lower portions having gradually reduced thickness when extending deeper into trench 92. The lines 94A-S1 represent a possible sidewall of dielectric layer 94A, which has the bottom end between the top surface of STI region 26 and the bottom end of trench 92. The lower part of dielectric layer 94A having sidewall 94A-S1 also has gradually reduced thickness when extending deeper into trench 92. The lines 94A-S2 represent an alternative profile of dielectric layer 94A, which fully covers all sidewalls of STI region 26 and gate stacks 70, which sidewalls are exposed to trench 92. The bottom portion of dielectric layer 94A, however, has smaller thicknesses than the respective upper portions.

Referring to FIG. 19, dielectric layer 94B is deposited, for example, using ALD, PEALD, CVD, PECVD, or the like. The respective process is illustrated as process 312 in the process flow 300 as shown in FIG. 23. In accordance with some embodiments, dielectric layer 94B has a higher k value and a higher density than dielectric layer 94B. For example, dielectric layer 94B may be a high-k dielectric layer having a k value higher than about 6, and may be higher than about 7. The k value difference (k94B−k94A) may be greater than about 2 or greater than about 4, and may be in the range between about 2 and about 5, with the k values k94A and k94B being the k values of dielectric layers 94A and 94B, respectively.

Dielectric layer 94B may also be formed of or comprise a silicon-containing dielectric material. In accordance with some embodiments, dielectric layer 94B may be formed using a silicon-containing precursor, which may be free from carbon and nitrogen. For example, the silicon-containing precursor may comprise silane, disilane, DiChloroSilane, or the like, or combination thereof. With the using of these precursors, it is easier for the resulting dielectric layer 94B to be filled to the bottom of trench 92. In accordance with some embodiments, dielectric layer 94B may comprise silicon oxide (SiO₂), SiN, or the like. The formation may (or may not) also include other carbon and/or nitrogen containing precursors such as CO₂, NO, NO₂, N₂, NH₃, H₂, or the like, so that the resulting dielectric layer 94B may also comprise carbon and/or nitrogen. Accordingly, dielectric layer 94B may also comprise SiN, SiO, SiCON, SiCN, SiON, SiCO, or the like, or combinations thereof.

In accordance with some embodiments, dielectric layers 94A and 94B comprise different elements, wherein at least one of the elements (such as C and/or N) in one of dielectric layers 94A and 94B is not in the other when deposited. In accordance with alternative embodiments, dielectric layers 94A and 94B comprise same elements, and may or may not have the same composition. Throughout the description, when two layers are referred to as having the same composition, it means that the two layers have same elements, and the percentages of the corresponding elements in two layers are the same as each other. Conversely, when two layers are referred to as having different compositions, it means that at least one of the two layers either has at least one element not in the other layer, or the two layers have the same elements, but the percentages of the elements in two layers are different from each other.

In accordance with some embodiments, dielectric layers 94A and 94B have same elements but different compositions. For example, dielectric layers 94A and 94B may both comprise SiOCN, while the carbon atomic percentage of dielectric layer 94A is greater (for example, two time higher or more) than that in dielectric layer 94B. In accordance with alternative embodiments, dielectric layer 94A comprises carbon as deposited, while dielectric layer 94B is free from carbon when deposited.

In accordance with some embodiments, dielectric layers 94A and 94B have the same composition with the same elements and the same (or close, for example, with less 20 percent variation) composition. For example, both of dielectric layers 94A and 94B may comprise SiCON. The k value k94A of dielectric layer 94A, however, is lower than the k value k94B of dielectric layer 94B. The lower k value k94A may be achieved by using different precursors, different deposition methods, and/or different process conditions, so that the porosity of dielectric layer 94A is greater than the porosity of dielectric layer 94B, even if the compositions of dielectric layers 94A and 94B are the same or close to each other. For example, the porosity P94A of dielectric layer 94A may be in the range between about 20 percent and about 40 percent, and the porosity P94B of dielectric layer 94B may be smaller than about 10 percent or 5 percent. The porosity difference (P94A-P94B) may be greater than about 10 percent or greater than about 20 percent, and may be in the range between 10 percent and about 40 percent.

In accordance with some embodiments, dielectric layer 94B fully fills the remaining trench 92 remaining unfilled by dielectric layer 94A. Accordingly, no void is formed in dielectric layer 94B. In accordance with alternative embodiments, due to the greater thickness of dielectric layer 94A in upper portions than in deeper portions of trench 92, void 96 is formed. Void 96 is illustrated as being dashed to indicate it may or may not be formed. Since the dielectric layer 94A may fully cover the sidewalls of gate stacks 70 without covering the lower portions, the void 96 may be formed deep in trench 92. For example, the top end of void 96 may be lower than or level with the interface between STI region 26 and the overlying gate stacks 70A and 70B.

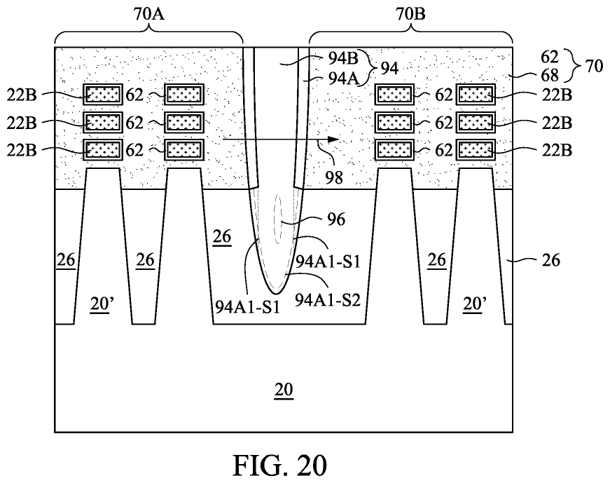

After the deposition of dielectric layers 94A and 94B, a planarization process such as a CMP process or a mechanical grinding process is performed. The respective process is illustrated as process 314 in the process flow 300 as shown in FIG. 23. The planarization process may be stopped on the top surfaces of gate stacks 70. The remaining portions of dielectric layers 94A and 94B are collectively referred to as gate isolation region 94 hereinafter, as shown in FIG. 20. After the process as shown in FIG. 20, the remaining processes as shown in FIGS. 13A, 13B, 14A, and 14B are performed to finish the formation of the GAA transistors 82.

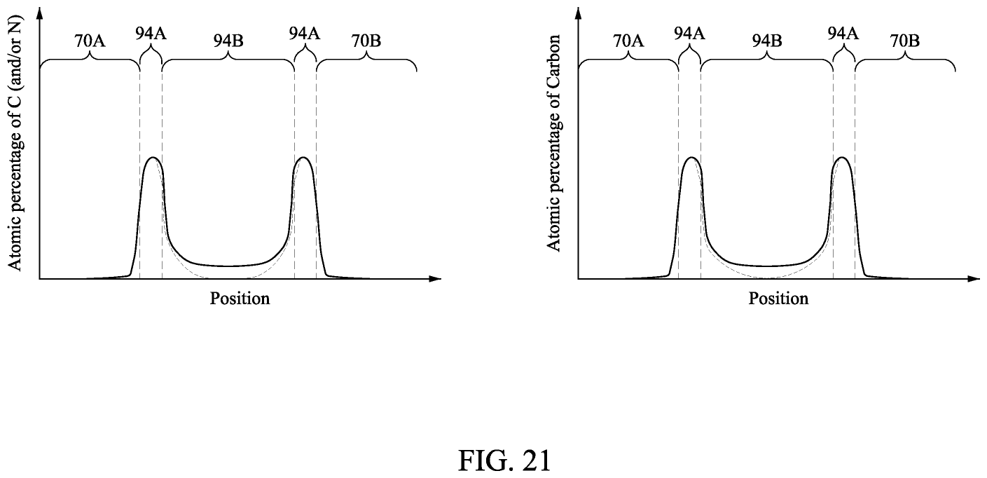

In accordance with some embodiments, dielectric layer 94A comprises carbon, while dielectric layer 94B is free from carbon, or have a lower atomic percentage of carbon than dielectric layer 94A. Accordingly, the peak atomic percentage of carbon (and/or nitrogen if dielectric layer 98B is also free from carbon and/or nitrogen when deposited) may be in dielectric layer 94A. FIG. 21 schematically illustrates a profile of carbon (and/or nitrogen) in accordance with some embodiments. The X-axis represents the positions corresponding to arrow 98 in FIG. 20. The Y-axis represents the atomic percentage of carbon (and/or nitrogen). It is shown that the peak percentage of carbon are in two portions of dielectric layer 94A, and reduce in gate stacks 70A and 70B and dielectric layer 94B. The dashed line represents an alternative embodiment in which dielectric layer 94B does not have carbon (and/or nitrogen), and carbon (and/or nitrogen) is not able to diffuse to the center of dielectric layer 94B.

The embodiments of the present disclosure have some advantageous features. When forming a gate isolation region (a CMG region), by forming a first dielectric layer to fill the trench and having a lower k value, the first dielectric layer has a greater effect on the reduction of the parasitic capacitance. The second dielectric layer has a higher k value and is denser, and has better ability of reducing leakage current. The difference in the compositions of the two dielectric layers of the gate isolation region may be observed, for example, using Transmission electron microscopes (TEM).

In accordance with some embodiments of the present disclosure, a method comprises forming a gate stack; etching the gate stack to form a trench penetrating through the gate stack, wherein a dielectric isolation region underlying the gate stack is exposed to the trench, and a first portion and a second portion of the gate stack are separated by the trench; performing a first deposition process to form a first dielectric layer extending into the trench and lining sidewalls of the first portion and the second portion of the gate stack, wherein the first dielectric layer has a first dielectric constant; and performing a second deposition process to form a second dielectric layer on the first dielectric layer, wherein the second dielectric layer fills the trench, and the second dielectric layer has a second dielectric constant greater than the first dielectric constant.

In an embodiment, the first dielectric layer is deposited using aminosilane as a first precursor. In an embodiment, the second dielectric layer is deposited using a second precursor selected from the group consisting of silane, disilane, DiChloroSilane, and combinations thereof, and wherein the first dielectric layer and the second dielectric layer comprise same elements. In an embodiment, the first dielectric layer and the second dielectric layer have a same composition. In an embodiment, the first dielectric layer has a higher porosity than the second dielectric layer. In an embodiment, the first dielectric layer is deposited using N₂, NH₃, and Ar as additional process gases.

In an embodiment, the method further comprises forming a protruding fin, wherein the gate stack is formed on the protruding fin; etching the protruding fin to form source/drain recesses; and forming source and drain regions in the source/drain recesses. In an embodiment, the method further comprises performing a planarization process to remove portions of the first dielectric layer and the second dielectric layer higher than a top surface of the gate stack to form a gate isolation region. In an embodiment, the first dielectric layer has a bottom surface higher than a bottom end of the trench. In an embodiment, the second dielectric layer is in physical contact with the dielectric isolation region.

In accordance with some embodiments of the present disclosure, a structure comprises a semiconductor substrate comprising a bulk portion; a dielectric isolation region over the bulk portion of the semiconductor substrate; a semiconductor region aside of the dielectric isolation region, wherein the semiconductor region comprises a portion higher than the dielectric isolation region; a first gate stack and a second gate stack over the dielectric isolation region; and a gate isolation region between and physical contacting the first gate stack and the second gate stack, wherein the gate isolation region extends from a top surface level of the first gate stack to a level lower than a bottom surface level of the first gate stack, and wherein the gate isolation region comprises a first dielectric layer comprising a low-k dielectric material; and a second dielectric layer comprising a high-k dielectric material, wherein the first dielectric layer comprises a portion between and contacting the second dielectric layer and the first gate stack.

In an embodiment, the first dielectric layer comprises silicon and carbon. In an embodiment, the first dielectric layer comprises SiOCN. In an embodiment, the first dielectric layer and the second dielectric layer comprise same elements, and the first dielectric layer has a higher porosity than the second dielectric layer. In an embodiment, the first dielectric layer and the second dielectric layer have a same composition. In an embodiment, a part of the second dielectric layer physically contacts the dielectric isolation region.

In accordance with some embodiments of the present disclosure, a structure comprises a first GAA transistor comprising a first gate stack; a second GAA transistor comprising a second gate stack; and a gate isolation region between and contacting the first gate stack and the second gate stack, wherein the gate isolation region comprises a first dielectric layer comprising SiOCN, wherein the first dielectric layer physically contacts the first gate stack and the second gate stack, and wherein the first dielectric layer has a first dielectric constant; and a second dielectric layer on the first dielectric layer, wherein the second dielectric layer has a second dielectric constant higher than the first dielectric constant.

In an embodiment, the first dielectric layer has lower portions thinner than upper portions, and bottom ends of the first dielectric layer are level with or lower than bottom surfaces of the first gate stack and the second gate stack. In an embodiment, the second dielectric layer also comprises SiOCN, and the first dielectric layer has a higher porosity than the second dielectric layer. In an embodiment, the structure further comprises a dielectric isolation region underlying and contacting both of the first gate stack and the second gate stack, wherein a bottom portion of the gate isolation region is in the dielectric isolation region, and wherein a bottom portion of the second dielectric layer physically contacts the dielectric isolation region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack;
etching the gate stack to form a trench penetrating through the gate stack, wherein a dielectric isolation region underlying the gate stack is exposed to the trench, and a first portion and a second portion of the gate stack are separated by the trench;
performing a first deposition process to form a first dielectric layer extending into the trench and lining sidewalls of the first portion and the second portion of the gate stack, wherein the first dielectric layer has a first dielectric constant; and
performing a second deposition process to form a second dielectric layer on the first dielectric layer, wherein the second dielectric layer fills the trench, and the second dielectric layer has a second dielectric constant greater than the first dielectric constant.

2. The method of claim 1, wherein the first dielectric layer is deposited using aminosilane as a first precursor.

3. The method of claim 2, wherein the second dielectric layer is deposited using a second precursor selected from the group consisting of silane, disilane, DiChloroSilane, and combinations thereof, and wherein the first dielectric layer and the second dielectric layer comprise same elements.

4. The method of claim 3, wherein the first dielectric layer and the second dielectric layer have a same composition.

5. The method of claim 4, wherein the first dielectric layer has a higher porosity than the second dielectric layer.

6. The method of claim 2, wherein the first dielectric layer is deposited using N₂, NH₃, and Ar as additional process gases.

7. The method of claim 1 further comprising:
forming a protruding fin, wherein the gate stack is formed on the protruding fin;
etching the protruding fin to form source/drain recesses; and
forming source and drain regions in the source/drain recesses.

8. The method of claim 1 further comprising performing a planarization process to remove portions of the first dielectric layer and the second dielectric layer higher than a top surface of the gate stack to form a gate isolation region.

9. The method of claim 1, wherein the first dielectric layer has a bottom surface higher than a bottom end of the trench.

10. The method of claim 1, wherein the second dielectric layer is in physical contact with the dielectric isolation region.

11. A method comprising:
forming a dielectric isolation region over a bulk portion of a semiconductor substrate, wherein a semiconductor region is aside of the dielectric isolation region, and wherein the semiconductor region comprises a portion higher than the dielectric isolation region;
forming a replacement gate stack over the dielectric isolation region;
etching the replacement gate stack to form a first gate stack and a second gate stack; and
forming a gate isolation region between and physical contacting the first gate stack and the second gate stack, wherein the gate isolation region extends from a top surface level of the first gate stack to a level lower than a bottom surface level of the first gate stack, and wherein the forming the gate isolation region comprises:
depositing a first dielectric layer comprising a low-k dielectric material; and
depositing a second dielectric layer comprising a high-k dielectric material, wherein the first dielectric layer comprises a portion between and contacting the second dielectric layer and the first gate stack.

12. The method of claim 11, wherein the depositing the first dielectric layer comprises depositing a silicon-and-carbon containing dielectric layer.

13. The method of claim 12, wherein the depositing the first dielectric layer comprises depositing SiOCN.

14. The method of claim 11, wherein the first dielectric layer and the second dielectric layer are deposited as comprising same elements, and the first dielectric layer has a higher porosity than the second dielectric layer.

15. The method of claim 14, wherein the first dielectric layer and the second dielectric layer are deposited as having a same composition.

16. The method of claim 11, wherein a part of the second dielectric layer physically contacts the dielectric isolation region.

17. A structure comprising:
a first Gate-All-Around (GAA) transistor comprising a first gate stack;
a second GAA transistor comprising a second gate stack; and
a gate isolation region between and contacting the first gate stack and the second gate stack, wherein the gate isolation region comprises:
a first dielectric layer comprising SiOCN, wherein the first dielectric layer physically contacts the first gate stack and the second gate stack, and wherein the first dielectric layer has a first dielectric constant; and
a second dielectric layer on the first dielectric layer, wherein the second dielectric layer has a second dielectric constant higher than the first dielectric constant.

18. The structure of claim 17, wherein the first dielectric layer has lower portions thinner than upper portions, and bottom ends of the first dielectric layer are level with or lower than bottom surfaces of the first gate stack and the second gate stack.

19. The structure of claim 17, wherein the second dielectric layer also comprises SiOCN, and the first dielectric layer has a higher porosity than the second dielectric layer.

20. The structure of claim 17 further comprising a dielectric isolation region underlying and contacting both of the first gate stack and the second gate stack, wherein a bottom portion of the gate isolation region is in the dielectric isolation region, and wherein a bottom portion of the second dielectric layer physically contacts the dielectric isolation region.
